(19) United States
(12) Patent Application Publication
(10) Pub. No.: US 2026/0056442 A1
(43) Pub. Date: Feb. 26, 2026

(54) OPTICAL APPARATUS AND WAVELENGTH-TUNABLE LASER

(71) Applicant: FURUKAWA ELECTRIC CO., LTD., Tokyo (JP)

(72) Inventors: Kazuki YAMAOKA, Tokyo (JP); Maiko ARIGA, Tokyo (JP)

(73) Assignee: FURUKAWA ELECTRIC CO., LTD., Tokyo (JP)

(21) Appl. No.: 19/372,412

(22) Filed: Oct. 29, 2025

Related U.S. Application Data
(63) Continuation of application No. PCT/JP2025/003031, filed on Jan. 30, 2025.

(30) Foreign Application Priority Data
Feb. 6, 2024 (JP) 2024-016582

(51) Int. Cl. G02F 1/21; G02F 1/01; H01S 5/02325; H01S 5/06

(52) U.S. Cl. CPC G02F 1/213; G02F 1/0147; H01S 5/02325; H01S 5/0612; G02F 2203/055; G02F 2203/21

(57) ABSTRACT

An optical apparatus includes: a base; a plurality of optical components fixed to the base, the plurality of optical components including an etalon filter; and an electric heating member integrated with the etalon filter, the electric heating member including a transparent electric heating element configured to be optically in series with the etalon filter and transmit light.

This application is a continuation of International Application No. PCT/JP2025/003031, filed on Jan. 30, 2025 which claims the benefit of priority of the prior Japanese Patent Application No. 2024-016582, filed on Feb. 6, 2024, the entire contents of which are incorporated herein by reference.

### BACKGROUND

The present disclosure relates to an optical apparatus and a wavelength-tunable laser.

This application is subject to Article 17, Paragraph 1 of the Industrial Technology Enhancement Act, and Reiwa 4, National Institute of Information and Communications Technology “Commissioned Research and Development for Innovative Information and Communications Technology/Research and Development for Bandwidth-expansion Optical Node Technology for Beyond 5G High-speed, Large-capacity Networks and Bandwidth-expansion Optical Node technology for Bitrate-distance product expansion in Optical Network”.

In the related art, a chip-integrated wavelength-tunable laser is known (Japanese Patent No. 2687464). In the wavelength-tunable laser disclosed in Japanese Patent No. 2687464, an amplification unit that emits light and amplifies light and an optical filter that has predetermined wavelength characteristics are integrated.

### SUMMARY

In the configuration disclosed in Japanese Patent No. 2687464, for example, when an amount of current in the amplification unit is increased to increase output power of laser, heat that is generated in the amplification unit may be transmitted to the optical filter and affect the wavelength characteristics of the optical filter. Therefore, it is preferable to individually adjust temperature of the optical filter. Further, in this case, it is preferable to adjust the temperature of the optical filter with improved accuracy.

There is a need for an optical apparatus and a wavelength-tunable laser that are improved and novel and that are able to individually adjust temperature of an optical filter with improved accuracy.

According to one aspect of the present disclosure, there is provided an optical apparatus including: a base; a plurality of optical components fixed to the base, the plurality of optical components including an etalon filter; and an electric heating member integrated with the etalon filter, the electric heating member including a transparent electric heating element configured to be optically in series with the etalon filter and transmit light.

According to another aspect of the present disclosure, there is provided a wavelength-tunable laser including: an optical amplification unit configured to generate light, amplify the light, and output the light from a first end portion and a second end portion that is on an opposite side of the first end portion; a first mirror configured to reflect the light output from the first end portion; a second mirror configured to reflect the light output from the second end portion; an etalon filter arranged between the optical amplification unit and the first mirror or the second mirror, the etalon filter having predetermined wavelength characteristics and being configured to transmit the light output from the optical amplification unit; and an electric heating member integrated with the etalon filter, the electric heating member including a transparent electric heating element configured to be optically in series with the etalon filter and transmit the light.

### BRIEF DESCRIPTION OF THE DRAWINGS

FIG. 1 is an exemplary and schematic plan view illustrating an optical apparatus of a first embodiment in which a top cover is removed;

FIG. 2 is an exemplary and schematic side view illustrating a part of the optical apparatus of the first embodiment;

FIG. 3 is an exemplary and schematic front view illustrating an electric heating member that is included in the optical apparatus of the first embodiment;

FIG. 4 is an exemplary and schematic plan view illustrating an optical apparatus of a second embodiment in which a top cover is removed;

FIG. 5 is an exemplary and schematic side view illustrating a part of the optical apparatus of the second embodiment;

FIG. 6 is an exemplary and schematic plan view illustrating an optical apparatus of a third embodiment in which a top cover is removed;

FIG. 7 is an exemplary and schematic plan view illustrating an optical apparatus of a fourth embodiment in which a top cover is removed;

FIG. 8 is an exemplary and schematic plan view illustrating an optical apparatus of a fifth embodiment in which a top cover is removed;

FIG. 9 is an exemplary and schematic plan view illustrating an optical apparatus of a sixth embodiment in which a top cover is removed;

FIG. 10 is an exemplary and schematic plan view illustrating an optical apparatus of a seventh embodiment in which a top cover is removed;

FIG. 11 is an exemplary and schematic side view illustrating a part of an optical apparatus of an eighth embodiment;

FIG. 12 is an exemplary and schematic side view illustrating a part of an optical apparatus of a ninth embodiment;

FIG. 13 is an exemplary and schematic side view illustrating a part of an etalon filter and an electric heating member that are included in an optical apparatus of a tenth embodiment;

FIG. 14 is an exemplary and schematic front view illustrating an electric heating member and a resistance temperature detector wiring layer that are included in an optical apparatus of an eleventh embodiment;

FIG. 15 is a cross-sectional view taken along a line XV-XV in FIG. 14;

FIG. 16 is an exemplary and schematic plan view illustrating a part of an internal configuration of the optical apparatus of the eleventh embodiment;

FIG. 17 is a cross-sectional view, at the same position as in FIG. 15, of an etalon filter, an electric heating member, and a resistance temperature detector wiring layer that are included in an optical apparatus of a twelfth embodiment; and

FIG. 18 is an exemplary and schematic plan view illustrating an etalon filter, an electric heating member, and a resistance temperature detector wiring layer that are included in an optical apparatus of a thirteenth embodiment.

### DETAILED DESCRIPTION

Exemplary embodiments will be disclosed below. Configurations of the embodiments and operation and results (effects) that are implemented by the configurations described below are examples. The present disclosure may be implemented by configurations other than the configurations disclosed in the embodiments below. In addition, according to the present disclosure, it is possible to achieve at least one of various kinds of effects (including derivative effects) that are achieved by the configurations.

A plurality of embodiments described below include same components. Therefore, according to the components of each of the embodiments, it is possible to achieve the same operation and effects based on the same components. Further, in the following, the same components are denoted by the same reference symbols, and repeated explanation will be omitted.

Furthermore, in the present specification, ordinal numbers are assigned, for the sake of convenience, to distinguish among parts, members, directions, beams of light, and the like. Meanwhile, the ordinal numbers do not indicate priority and order, and do not identify numbers.

Moreover, in each of the drawings, an X direction is indicated by an arrow X, a Y direction is indicated by an arrow Y, and a Z direction is indicated by an arrow Z. The X direction, the Y direction, and the Z direction intersect and are perpendicular to one another. Meanwhile, each of the drawings is schematic, and shapes, dimensions, and the like of all of units may be different from actual ones.

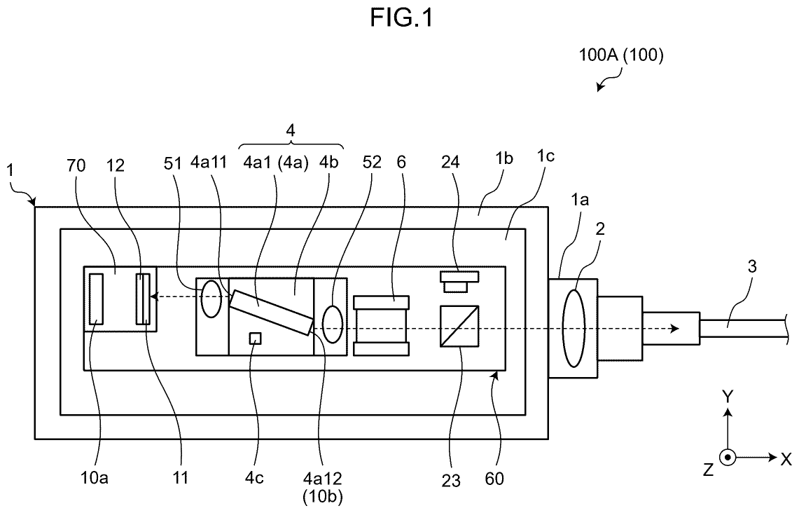

FIG. 1 is a plan view illustrating an optical module 100A (100) of a first embodiment in which a top cover is removed. The optical module 100A (100) is one example of an optical apparatus that includes a wavelength-tunable laser.

As illustrated in FIG. 1, the optical module 100A includes a housing 1. The housing 1 includes an output port 1a, four side walls 1b, a bottom wall 1c, and the top cover (not illustrated).

The bottom wall 1c is a plate-shaped member that is located at an end portion in an opposite direction of the Z direction. The bottom wall 1c intersects and is perpendicular to the Z direction, and extends in the X direction and the Y direction with an approximately constant thickness in the Z direction. The bottom wall 1c is made of a material with high thermal conductivity, such as tungsten-copper (CuW), molybdenum-copper (CuMo), or aluminum oxide (Al₂O₃), for example.

Each of the side walls 1b is a plate-shaped member.

Further, each of the side walls 1b is approximately perpendicular to the bottom wall 1c, is perpendicular to the X direction or the Y direction, and extends in the Z direction.

The output port 1a is arranged in the side wall 1b that is located in an end portion in the X direction. A lens 2 is housed in the output port 1a. Further, the output port 1a supports an optical fiber 3 that outputs output light to the outside.

The top cover is a plate-shaped member that is located in an end portion in the Z direction. The top cover intersects and is perpendicular to the Z direction, and extends in the X direction and the Y direction with an approximately constant thickness in the Z direction. The top cover is approximately parallel to the bottom wall 1c.

The output port 1a, the side walls 1b, and the top cover are made of a material with a low thermal expansion coefficient, such as a Fe—Ni—Co alloy or aluminum oxide (Al₂O₃), for example.

A chamber in the housing 1 is, for example, hermetically sealed. In the housing 1, for example, inert gas, such as nitrogen gas, may be housed. In this case, the nitrogen gas is one example of gas.

In the housing 1, components, such as a chip on submount 4, lenses 51 and 52, an etalon filter 11, a mirror 10a, an optical isolator 6, a beam splitter 23, a photodiode 24, and a carrier 60, are housed. The components are supported by the housing 1 directly or indirectly via a different member, a different component, or the like. Among the components, the chip on submount 4, the lenses 51 and 52, the mirror 10a, the etalon filter 11, the optical isolator 6, the beam splitter 23, and the photodiode 24 are examples an optical component. The optical component is, for example, a component that outputs light, receives light, transmits light, affects light, or the like. Meanwhile, in the housing 1, an optical component other than the components as described above, a component, such as an electronic component or an electrical component, that is different from the optical component, or the like may be housed and supported. The housing 1 is one example of a base.

Further, in the present embodiment, the chip on submount 4, the lenses 51 and 52, the etalon filter 11, the mirror 10a, the optical isolator 6, the beam splitter 23, and the photodiode 24 are supported on the carrier 60 directly or indirectly via a different member. The carrier 60 is, for example, a Peltier module that has a temperature adjustment function. In this case, the carrier 60 is one example of a temperature control mechanism that is able to adjust temperature of a laser element 4a. The Peltier module will be described in detail later. Meanwhile, it may be possible to arrange a temperature control mechanism, such as a heater as a resistive heating module, that is different from the Peltier module, in accordance with the chip on submount 4, for example.

The chip on submount 4 includes the laser element 4a, a submount 4b, and a thermistor 4c. The laser element 4a is a semiconductor laser element. The laser element 4a includes an optical amplification unit 4a1. The chip on submount 4 may also be referred to as a light emitting unit.

The optical amplification unit 4a1 includes a laser medium, such as a semiconductor active layer, generates light in accordance with a supplied current, and amplifies the light. The optical amplification unit 4a1 emits light from one end portion 4a11 and another end portion 4a12 on the opposite side of the end portion 4a11. The end portion 4a11 is one example of a first end portion, and the end portion 4a12 is one example of a second end portion.

A mirror 10b is arranged on the end portion 4a12. The mirror 10b reflects at least a part of incoming light. In the present embodiment, the mirror 10b reflects a part of light that is output from the optical amplification unit 4a1, inputs the reflected light to the optical amplification unit 4a1, and transmits a part of the light that is output from the optical amplification unit 4a1. The mirror 10b is, for example, a dielectric multilayer mirror. The mirror 10b is one example of a second mirror.

The submount 4b supports the laser element 4a. The submount 4b is made of an insulating material with high thermal conductivity. The thermistor 4c may also be referred to as a temperature sensor. The thermistor 4c is mounted on, for example, the submount 4b.

Light that is output from the end portion 4a11 of the optical amplification unit 4a1 transmits through the lens 51. The lens 51 is, for example, a collimator lens.

Light that has passed through the lens 51 reaches the mirror 10a via the etalon filter 11.

The etalon filter 11 has predetermined wavelength characteristics, and transmits light with a wavelength corresponding to the wavelength characteristics. The etalon filter 11 includes a body that has end faces that are formed as parallel planes, and a dielectric film that is formed on each of the end faces and reflects or transmits light at predetermined reflectivity. The body is made of, for example, glass or silicon. The etalon filter 11 intersects the X direction and is spreading with an approximately constant height in the X direction, and has an approximately plate-like shape.

A heater 12 is arranged on the end face of the etalon filter 11. In the present embodiment, the etalon filter 11 and the heater 12 constitute a sub assembly. The heater 12 changes an optical path length of the etalon filter 11, and is accordingly able to change the wavelength characteristics of the etalon filter 11. The heater 12 generates heat from supplied electricity, and heats the etalon filter 11. The heater 12 is one example of an electric heating member. The heater 12 will be described in detail later.

The mirror 10a reflects at least a part of incoming light. In the present embodiment, the mirror 10a reflects entire light that arrives at the mirror 10a such that the entire light returns to the etalon filter 11. The mirror 10a is, for example, a dielectric multilayer mirror. The mirror 10a is one example of a first mirror.

Light that is output from the end portion 4a12 of the optical amplification unit 4a1 and that transmits through the mirror 10b reaches the optical isolator 6 via the lens 52. The lens 52 is, for example, a collimator lens.

The optical isolator 6 transmits incoming light, in this case, the light that comes from the lens 52, toward the beam splitter 23, and blocks returning light from the beam splitter 23.

The beam splitter 23 outputs most part of the light to the lens 2 and outputs a part of the light to the photodiode 24. The lens 2 condenses the light that comes from the beam splitter 23 and couples the light with the optical fiber 3.

The photodiode 24 receives the light from the beam splitter 23, and outputs a detection signal corresponding to intensity of the received light. The detection signal is input to a controller (not illustrated) via wire (not illustrated). The controller controls operation of the laser element 4a based on the detection signal from the photodiode 24.

In this configuration, the optical amplification unit 4a1 and the etalon filter 11 are arranged between the mirror 10a and the mirror 10b, so that a resonance mechanism in which light at a predetermined wavelength moves back and forth and resonates between the mirror 10a and the mirror 10b is constituted. In the resonance mechanism, it is possible to change a resonant wavelength by changing the optical path length by changing temperature of the etalon filter 11.

Furthermore, in this configuration, the lens 51 is arranged between the laser element 4a and the etalon filter 11, so that it is possible to increase a distance between the optical amplification unit 4a1 of the laser element 4a and the etalon filter 11. The optical amplification unit 4a1 generates heat by operation. Therefore, if the distance between the optical amplification unit 4a1 and the etalon filter 11 is short, it may be difficult to adjust the temperature of the etalon filter 11 by the heater 12 with high accuracy due to the heat that is generated by the optical amplification unit 4a1. In this regard, in the present embodiment, by arranging the lens 51, it is possible to increase the distance between the optical amplification unit 4a1 and the etalon filter 11. Therefore, it is possible to reduce thermal influence of the optical amplification unit 4a1 on the etalon filter 11, so that it is possible to perform temperature adjustment and wavelength control on the etalon filter 11 by the heater 12 with improved accuracy. The optical amplification unit 4a1 is one example of a heating element.

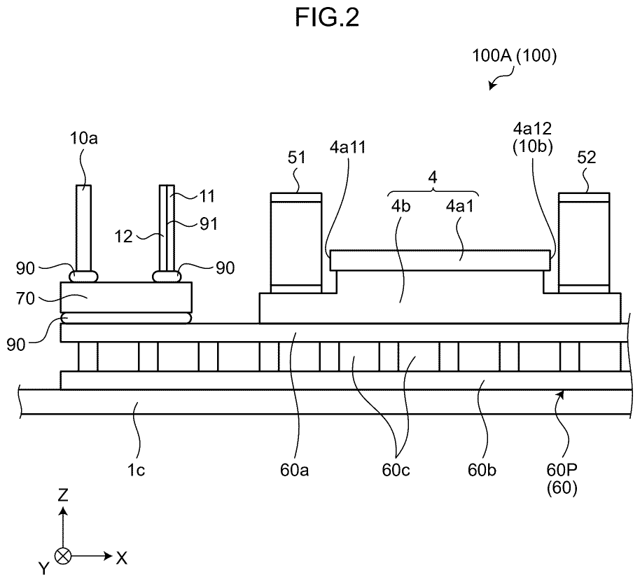

FIG. 2 is a side view of a part of the optical module 100A. As described above, in the present embodiment, the carrier 60 is configured as a Peltier module 60P. As illustrated in FIG. 2, the Peltier module 60P includes a first substrate 60a, a second substrate 60b, and a plurality of thermoelectric elements 60c. The thermoelectric elements 60c are columnar semiconductor elements that are arranged between the first substrate 60a and the second substrate 60b. The thermoelectric elements 60c are made of P-type semiconductors or N-type semiconductors, such as bismuth telluride-based semiconductors. The plurality of thermoelectric elements 60c are connected in series so as to form p-n junction by a wiring pattern (not illustrated) that is arranged in the first substrate 60a and the second substrate 60b. Further, electricity is supplied from wire (not illustrated) to a circuit that includes the plurality of thermoelectric elements 60c that are connected in series via the wiring pattern, so that the Peltier module 60P absorbs or generates heat in accordance with a direction of a current of the electricity. The Peltier module 60P is able to adjust temperature of the laser element 4a in accordance with, for example, a detection value of the thermistor 4c, and is one example of the temperature control mechanism and one example of the heating element.

Furthermore, in the present embodiment, the sub assembly of the etalon filter 11 and the heater 12 and the mirror 10a are supported on the Peltier module 60P via a heat shielding member 70 that has lower thermal conductivity than the housing 1, the Peltier module 60P, a metal material, or the like. In other words, the heat shielding member 70 is arranged between a set of the sub assembly, which includes the etalon filter 11 and the heater 12, and the mirror 10a and the optical amplification unit 4a1 or the Peltier module 60P, and prevents thermal conduction between the components. The heat shielding member 70 is made of, for example, glass. With this configuration, it is possible to prevent decrease in accuracy of a temperature adjustment function of the heater 12 with respect to the etalon filter 11, due to heat that comes from the Peltier module 60P in accordance with temperature adjustment or heat that is transmitted from the optical amplification unit 4a1 via the Peltier module 60P. Meanwhile, the heat shielding member 70 has a block-like shape, but embodiments are not limited to this example. For example, the heat shielding member 70 may include a hollow portion.

In this configuration, the etalon filter 11 and the heater 12 are integrated via a bonding material 91. Further, the heat shielding member 70 is fixed onto the carrier 60 via a bonding material 90, and the sub assembly of the etalon filter 11 and the heater 12 and the mirror 10a are fixed onto the heat shielding member 70 via the bonding material 90. In this case, heat shielding property of the bonding material 90 is higher than heat shielding property of the bonding material 91. In other words, thermal conductivity of the bonding material 91 is higher than thermal conductivity of the bonding material 90. With this configuration, it is possible to further prevent thermal conduction from the Peltier module 60P or the optical amplification unit 4a1 to the etalon filter 11, the heater 12, and the mirror 10a. Further, it is possible to allow the heater 12 to more efficiently and promptly heat the etalon filter 11, so that it is possible to control temperature and an optical wavelength of the etalon filter 11 with improved accuracy. Furthermore, it is possible to further improve responsiveness against wavelength control. The bonding material 90 is one example of a first bonding material, and the bonding material 91 is one example of a second bonding material.

Moreover, the etalon filter 11, the heater 12, and the mirror 10a are supported on the Peltier module 60P together with the chip on submount 4 and the lenses 51 and 52. With this configuration, because of the temperature adjustment function of the Peltier module 60P, for example, it is possible to prevent decrease in coupling efficiency among optical components due to a change in a relative positional relationship among the optical components.

As illustrated in FIG. 2, the heater 12 is integrated with the etalon filter 11 and comes into contact with the etalon filter 11 in an overlapping manner in a thickness direction (X direction). Meanwhile, arrangement of the etalon filter 11 and the heater 12 in the X direction may be inverted.

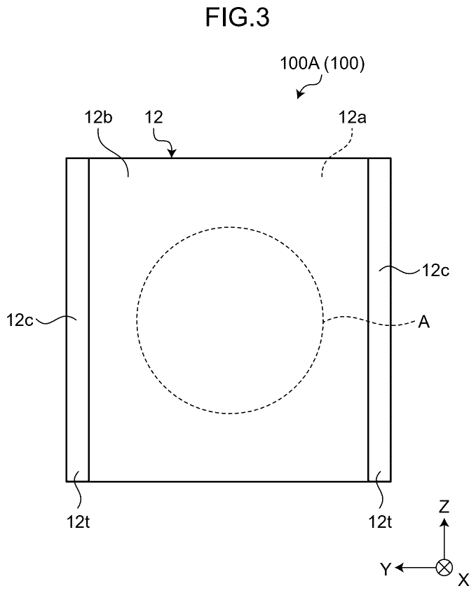

FIG. 3 is a front view of the heater 12. The heater 12 includes a transparent base material 12a, a transparent electric heating element 12b, and two wire units 12c. The wire units 12c are electrically connected to the transparent electric heating element 12b, and supply electricity to the transparent electric heating element 12b.

As illustrated in FIG. 3, the transparent base material 12a has an approximately plate-like shape, intersects the X direction, and is spreading with an approximately constant height in the X direction. The transparent base material 12a is made of, for example, glass or silicon.

As illustrated in FIG. 3, the transparent electric heating element 12b is formed on an end face (surface) of the transparent base material 12a in a thickness direction (opposite direction of the X direction). In the present embodiment, the transparent electric heating element 12b is arranged on an opposite side of the etalon filter 11 across the transparent base material 12a. The transparent electric heating element 12b has a film-like shape, intersects the X direction, and is spreading with an approximately constant thickness in the X direction. The transparent base material 12a, the transparent electric heating element 12b, and the etalon filter 11 are arranged optically in series. Further, the transparent electric heating element 12b has transmittance of 85 [%] or more, for example. Specifically, the transparent electric heating element 12b is made of Indium Tin Oxide (ITO).

The two wire units 12c and 12c extend in the Z direction with predetermined widths in the Y direction, at end portions of the transparent base material 12a in the Y direction and an opposite direction of the Y direction. The wire units 12c are made of, for example, Cr—Ni deposited metal films, and laminated on the transparent electric heating element 12b. Further, the wire units 12c are non-transparent. The transparent electric heating element 12b and the wire units 12c are formed by, for example, vapor deposition, sputtering, or the like.

Furthermore, it is preferable to appropriately arrange a dielectric film on an end face of the heater 12 in an optical axis direction. It is preferable that the dielectric film is arranged on an end face of at least one of the transparent base material 12a and the transparent electric heating element 12b in the optical axis direction. In this configuration, by adjusting a film thickness of the dielectric film, it is possible to adjust reflectivity in accordance with a change in a refractive index, so that it is possible to achieve an anti-reflection effect or the like. Furthermore, the dielectric film may be formed of a reflective film. Moreover, by adjusting film thicknesses of the transparent electric heating element 12b, the dielectric film, and the etalon filter 11, it is possible to adjust reflectivity of two opposing reflective surfaces, so that it is possible to increase transmittance of the etalon filter 11. Furthermore, in this configuration, when the wire units 12c are arranged on the transparent electric heating element 12b, it is preferable to arrange the dielectric film in a region in which the wire units 12c are not arranged on the transparent electric heating element 12b.

In the heater 12 of this configuration, a light passing area A is set so as to be located in the transparent base material 12a and the transparent electric heating element 12b. In other words, the laser light transmits through the transparent base material 12a and the transparent electric heating element 12b. In contrast, the two wire units 12c are non-transparent, and therefore arranged so as to be located outside of the passing area A without overlapping with the passing area A. With this configuration, it is possible to arrange the passing area A in the transparent electric heating element 12b that is heated by application of electricity and further widen the transparent electric heating element 12b, so that it is possible to more efficiently and more promptly heat the light passing area in the etalon filter 11 by the transparent electric heating element 12b. Furthermore, it is possible to reduce an uneven heat value of the transparent electric heating element 12b depending on locations in the etalon filter 11, so that it is possible to more accurately perform temperature adjustment and wavelength control on the etalon filter 11 by the heater 12. Meanwhile, specifications, such as locations and shapes, of the transparent base material 12a, the transparent electric heating element 12b, and the wire units 12c are not limited to those illustrated in the example in FIG. 3, but may be arbitrarily changed.

Specifications, such as a material, a length, a width, and a thickness, of the heater 12, in particular, the transparent electric heating element 12b, are determined so as to achieve predetermined heating performance on the etalon filter 11 in accordance with a range of control over a wavelength of light. As one example, when the optical module 100A is used as a wavelength-tunable laser, the specifications of the heater 12 are determined such that the heater 12 is able to heat at least the passing area A of the etalon filter 11 to 150 degrees Celsius and change temperature of at least the light passing area of the etalon filter 11 in a range equal to or higher than normal temperature and equal to or lower than 150 degrees Celsius by changing electricity to be supplied.

Table 1 illustrates transmittance, surface resistivity, and power consumption in accordance with the film thickness of the transparent electric heating element 12b.

TABLE 1

| Film Thickness [Å] | 100 | 200 | 400 |
|---|---|---|---|
| Transmittance [%] | 96 | 92 | 85 |
| Surface Resistivity [Ω/sq] | 32.5 | 65.0 | 130.0 |
| Power Consumption [W] | 0.1 | 0.05 | 0.025 |

Through intensive research made by the inventors, as illustrated in Table 1, it was confirmed that, when the film thickness of the transparent electric heating element 12b (ITO) was equal to or larger than 100 Å and equal to or smaller than 400 Å, the transmittance was equal to or larger than 85% and equal to or smaller than 96%, the surface resistivity was equal to or larger than 32.5 Ω/sq and equal to or smaller than 130.0 Ω/sq, and the power consumption was equal to or larger than 0.025 W and equal to or smaller than 0.1 W, and, in this case, it was possible to increase the temperature from normal temperature to 150 degrees Celsius at voltage of equal to or smaller than 3 V and a current of equal to or smaller than 0.05 Å. Meanwhile, the wire units 12c were Cr—Ni laminated metal films and the film thicknesses were set to 2000 Å.

Furthermore, a Free spectral range (FSR) of the etalon filter 11 is represented by Expression (1) below.

$$FSR = {λ}^{2} / ( 2 nL cos θ + λ ) \qquad ( 1 )$$

Here, λ represents a wavelength, n represents a refractive index of the etalon filter 11 (body), L represents a thickness of the etalon filter 11 (body), and θ represents an inclination angle with respect to an optical axis of incident light in a thickness direction of the etalon filter 11. The refractive index n is 1.5 when the body of the etalon filter 11 is made of glass, and is 3.5 when the body of the etalon filter 11 is made of silicon. From the expression (1), when the FSR is set to 700 GHz, the thickness L is 0.14 millimeters (mm) when the body is made of glass, and the thickness L is 0.06 (mm) when the body is made of silicon. Furthermore, from the expression (1), when the FSR is set to 300 GHz, the thickness L is 0.34 millimeters (mm) when the body is made of glass, and the thickness L is 0.14 (mm) when the body is made of silicon. By integrating the etalon filter 11 with the transparent base material 12a of the heater 12, it is possible to increase rigidity and strength of the etalon filter 11 and the heater 12. It is preferable to set the thickness of the transparent base material 12a to 0.01 (mm) or more and 0.2 (mm) or less, and it is more preferable to set the thickness to 0.05 (mm) or more and 0.1 (mm) or less.

It may be possible to arrange, in the vicinity of the etalon filter 11, a temperature detection unit that detects temperature of the etalon filter 11 or the heater 12. The temperature detection unit is, for example, a thermistor, and may be arranged on a surface of the etalon filter 11, the heater 12, or the heat shielding member 70. In this case, in the temperature adjustment control on the etalon filter 11 using the heater 12, it may be possible to perform feedback control based on a detection value of the temperature detection unit.

As described above, in the present embodiment, the heater 12 (electric heating member) that heats the etalon filter 11 is integrated with the etalon filter 11. Therefore, it is possible to individually adjust the temperature of the etalon filter 11 by the heater 12 with improved accuracy. Further, in the present embodiment, the heater 12 includes the transparent base material 12a and the transparent electric heating element 12b, and the etalon filter 11, the transparent base material 12a, and the transparent electric heating element 12b are arranged optically in series. Therefore, it is possible to more efficiently and promptly heat the light passing area in the etalon filter 11 by the transparent electric heating element 12b. Furthermore, it is possible to reduce unevenness in heating by the transparent electric heating element 12b depending on locations in the etalon filter 11, so that it is possible to more accurately perform temperature adjustment and wavelength control on the etalon filter 11 by the heater 12.

Moreover, in the present embodiment, the heater 12 includes the transparent base material 12a, and the transparent electric heating element 12b is arranged in the transparent base material 12a. With this configuration, it is possible to more reliably support the transparent electric heating element 12b by the transparent base material 12a. Furthermore, it is possible to prevent an influence on the end face of the etalon filter 11 when the transparent electric heating element 12b is formed, so that it is possible to set the reflectivity and the transmittance at the end face of the etalon filter 11 with improved accuracy.

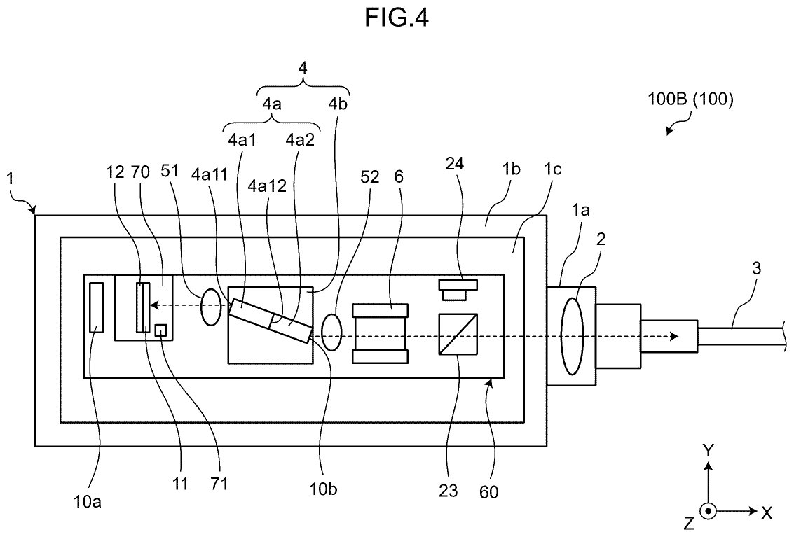

FIG. 4 is a plan view of an optical module 100B (100) of a second embodiment in which a top cover is removed. As illustrated in FIG. 4, in the optical module 100B, the laser element 4a includes the optical amplification unit 4a1 and an optical filter 4a2. The optical filter 4a2 is, for example, a distributed bragg reflector (DBR), a ring filter, a phase adjustment filter, a Mach-Zehnder type filter, or the like. In this manner, even when the laser element 4a includes one or more optical function units in addition to the optical amplification unit 4a1, it is possible to achieve the same effects as the first embodiment as described above. Furthermore, as compared to a case in which each of the optical function units is separately arranged, it is possible to more compactly configure the optical module 100.

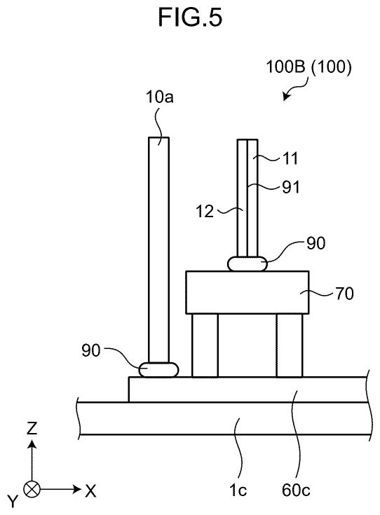

Moreover, FIG. 5 is a side view of a part of the optical module 100B. As illustrated in FIG. 5, in an optical module 100E, the etalon filter 11 and the heater 12 are mounted on the heat shielding member 70, but the mirror 10a is not mounted. Furthermore, as illustrated in FIG. 5, the heat shielding member 70 may have a girder structure. By adopting the girder structure, it is possible to further reduce a cross-sectional area of a heat conduction path in the heat shielding member 70, so that it is possible to further improve heat shielding performance. According to the present embodiment, it is possible to achieve the same effects as the first embodiment as described above, and compactly configure the heat shielding member 70.

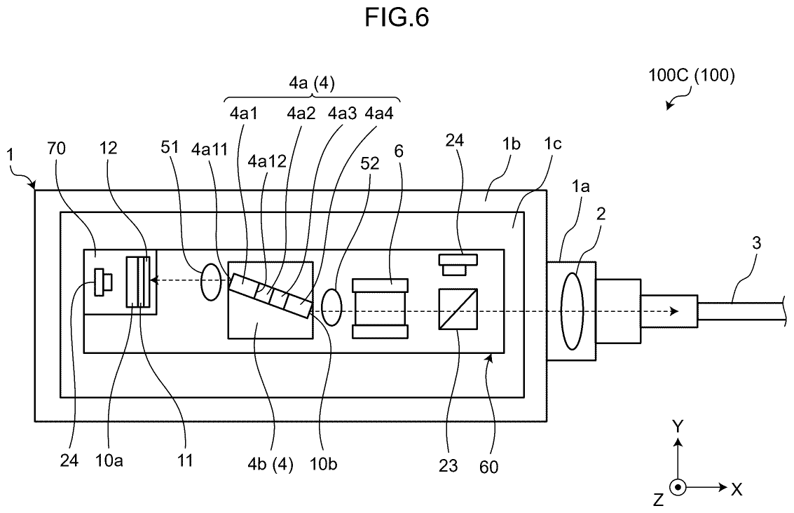

FIG. 6 is a plan view of an optical module 100C (100) of a third embodiment in which a top cover is removed. As illustrated in FIG. 6, in the optical module 100C, the laser element 4a includes the optical amplification unit 4a1, the optical filter 4a2, an optical filter 4a3, and a semiconductor optical amplifier (SOA) 4a4. Even in the present embodiment, the laser element 4a includes one or more optical function units in addition to the optical amplification unit 4a1, so that it is possible to more compactly configure the optical module 100 as compared to a case in which each of the optical function units is separately arranged.

Furthermore, as illustrated in FIG. 6, in the optical module 100C, the sub assembly of the etalon filter 11 and the heater 12 is integrated with the mirror 10a. The mirror 10a is, for example, a dielectric multilayer mirror. In this configuration, the heater 12 is arranged on the opposite side of the mirror 10a across the etalon filter 11. However, embodiments are not limited to this example, and the heater 12 may be arranged between the mirror 10a and the etalon filter 11. According to the present embodiment, the etalon filter 11, the heater 12, and the mirror 10a are integrated, so that it is possible to more compactly configure the optical module 100, which makes it possible to more easily ensure a space for arranging a different component, such as the photodiode 24.

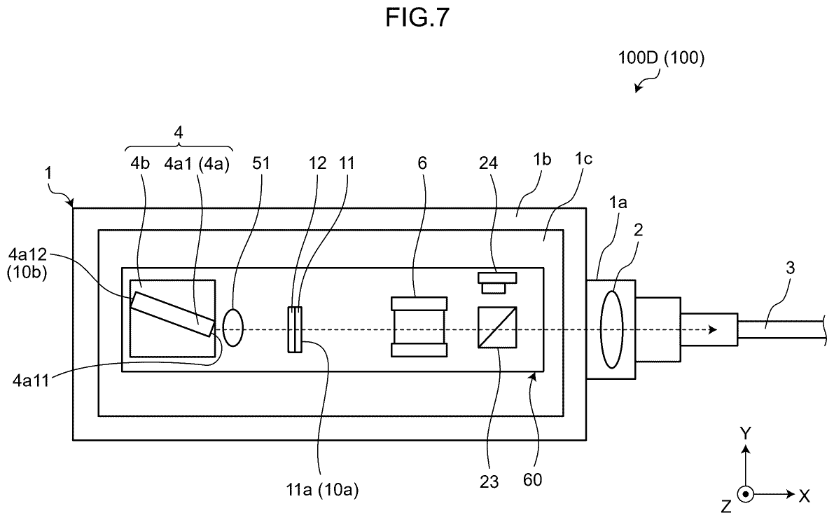

FIG. 7 is a plan view of an optical module 100D (100) of a fourth embodiment in which a top cover is removed. As illustrated in FIG. 7, the optical module 100D includes the single etalon filter 11 between the lens 51 and the optical isolator 6. Furthermore, the mirror 10b is arranged in the end portion 4a12 of the optical amplification unit 4a1, and the mirror 10a is arranged on an end face 11a of the etalon filter 11 on the opposite side of the lens 51. Even with this configuration, it is possible to achieve the same effects as the first embodiment as described above. Meanwhile, the heater 12 is located closer to the lens 51 than the etalon filter 11, but embodiments are not limited to this example, and the heater 12 may be arranged on the far side of the lens 51, that is, on the end face 11a in which the mirror 10a is arranged.

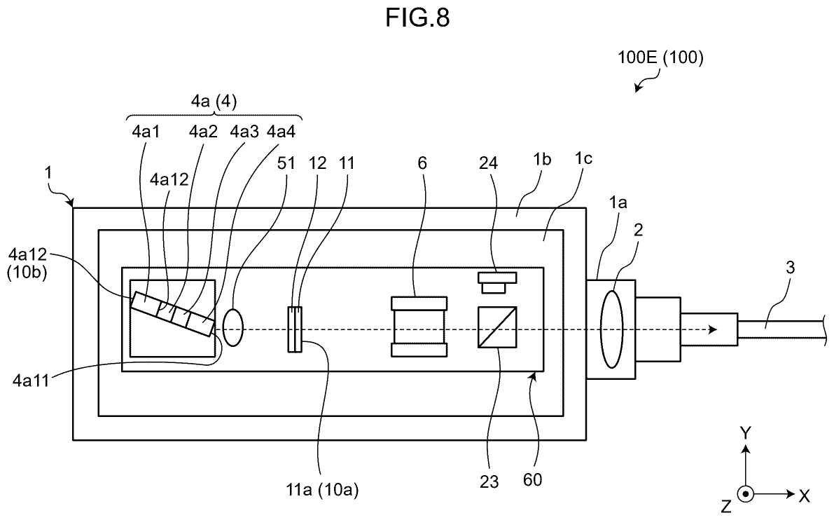

FIG. 8 is a plan view of the optical module 100E (100) of a fifth embodiment in which a top cover is removed. As illustrated in FIG. 8, in the optical module 100E, the laser element 4a includes the optical amplification unit 4a1, the optical filters 4a2 and 4a3, and the SOA 4a4. Even in the present embodiment, the laser element 4a includes one or more optical function units in addition to the optical amplification unit 4a1, so that it is possible to more compactly configure the optical module 100 as compared to a case in which each of the optical function units is separately arranged.

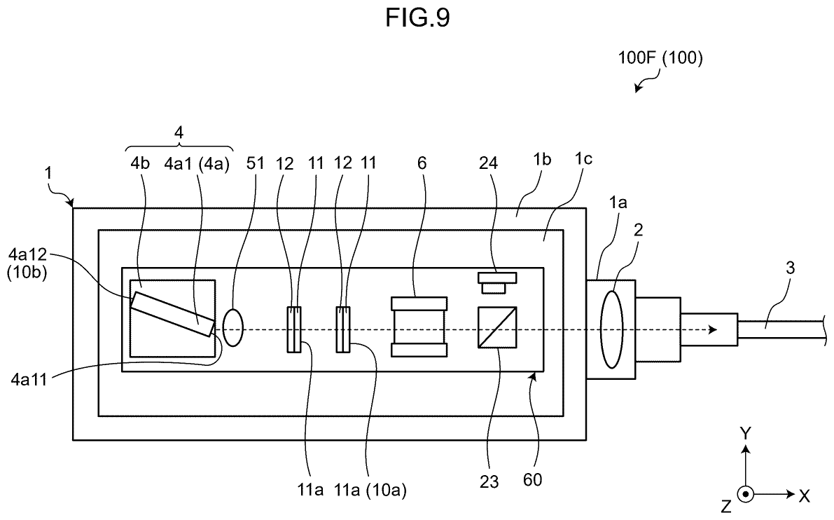

FIG. 9 is a plan view of an optical module 100F (100) of a sixth embodiment in which a top cover is removed. As illustrated in FIG. 9, the optical module 100F includes the two etalon filters 11 that are arranged in series between the lens 51 and the optical isolator 6. Furthermore, the mirror 10b is arranged on the end portion 4a12 of the optical amplification unit 4a1, and the mirror 10a is arranged on the end face 11a, which is on the opposite side of the lens 51, of the etalon filter 11 that is located on the farther side from the lens 51. Furthermore, the heater 12 is arranged on the end face of each of the etalon filters 11 on the closer sides of the lens 51. Even with this configuration, it is possible to achieve the same effects as the first embodiment as described above. Moreover, with this configuration, the number of the etalon filters 11 is increased, so that it is possible to further increase a controllable wavelength band. Meanwhile, the heaters 12 may be arranged on the end faces 11a of the etalon filters 11 on the opposite side of the lens 51.

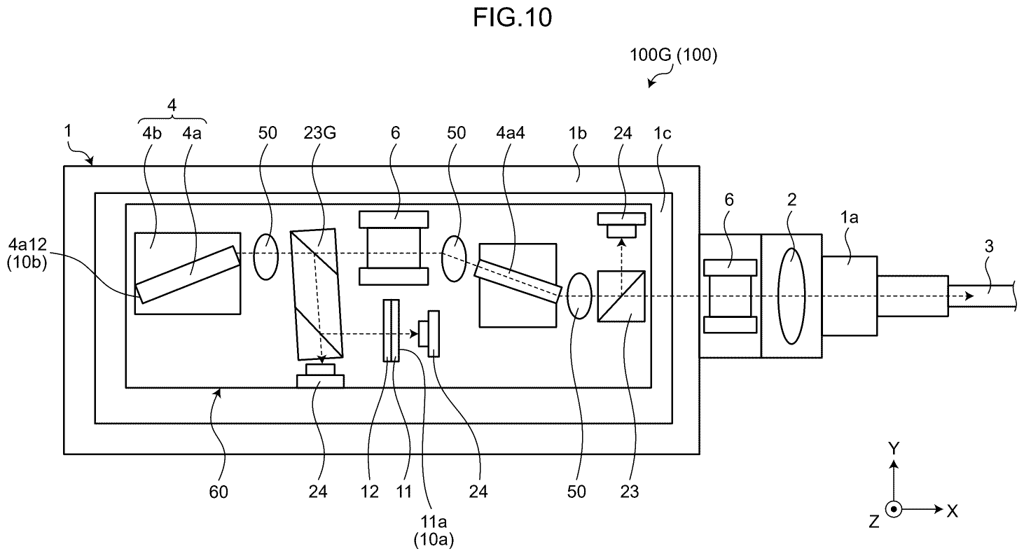

FIG. 10 is a plan view of an optical module 100G (100) of a seventh embodiment in which a top cover is removed. The optical module 100G includes the plurality of lenses 50, a beam splitter 23G, the SOA 4a4, and the like in addition to the same components as those of the first embodiment. Further, the lens 50 and the beam splitter 23G are arranged between the mirror 10a that is arranged on the end face 11a of the etalon filter 11 and the mirror 10b that is arranged on the end portion 4a12 of the optical amplification unit 4a1. The heater 12 is arranged on the end face of the etalon filter 11 on the opposite side of the end face 11a in which the mirror 10a is arranged. Even with this configuration, it is possible to achieve the same effects as the first embodiment as described above. Meanwhile, the heater 12 may be arranged on the end face 11a of the etalon filter 11 in which the mirror 10a is arranged.

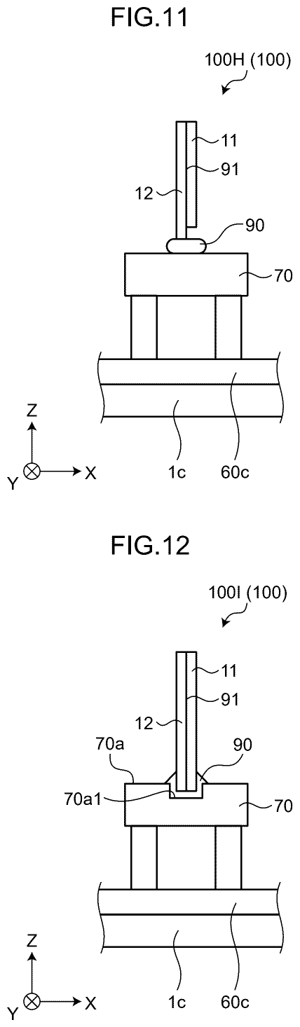

FIG. 11 is a side view of a part of an optical module 100H (100) of an eighth embodiment. In the present embodiment, the etalon filter 11 is supported by the heat shielding member 70 via the heater 12, instead of being directly supported by the heat shielding member 70. Specifically, in the present embodiment, the heater 12 is arranged between the etalon filter 11 and the optical amplification unit 4a1 or the Peltier module 60P. Even with this configuration, it is possible to achieve the same effects as the first embodiment as described above. Furthermore, with this configuration, it is possible to further reduce a thermal influence of the optical amplification unit 4a1 or the Peltier module 60P on the etalon filter 11, so that it is possible to perform temperature adjustment and wavelength control on the etalon filter 11 by the heater 12 with improved accuracy.

FIG. 12 is a side view of a part of an optical module 100I (100) of a ninth embodiment. In the present embodiment, the sub assembly of the etalon filter 11 and the heater 12 is fixed by the bonding material 90 while being housed in a recess 70a1 that is arranged in a top surface 70a of the heat shielding member 70. Even with this configuration, it is possible to achieve the same effects as the first embodiment as described above. Furthermore, with this configuration, it is possible to more reliably fix the etalon filter 11 and the heater 12 to the heat shielding member 70, and, due to a contact between a part of a side surface of the sub assembly to a side surface of the recess 70a1 for example, it is possible to further improve accuracy of a position and a posture (angle) of the sub assembly. Meanwhile, it may be possible to house only one of the etalon filter 11 and the heater 12 in the recess 70a1.

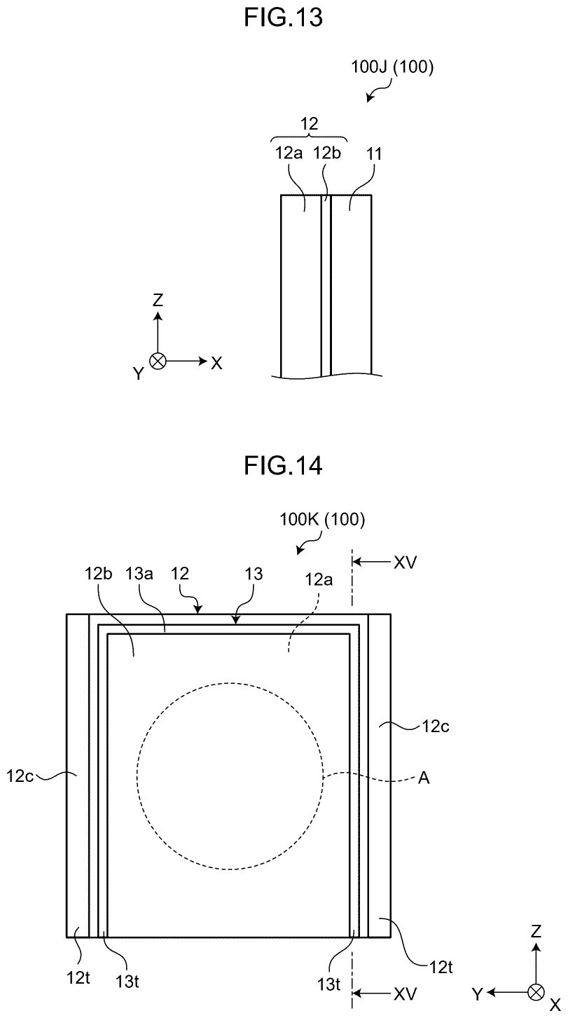

FIG. 13 is a side view of a part of an optical module 100J (100) of a tenth embodiment. In the present embodiment, the transparent electric heating element 12b is arranged between the etalon filter 11 and the transparent base material 12a. Even with this configuration, it is possible to achieve the same effects as the first embodiment as described above. Furthermore, with this configuration, it is possible to efficiently heat the etalon filter 11 by the transparent electric heating element 12b, so that it is possible to reduce power consumption due to heating of the etalon filter 11.

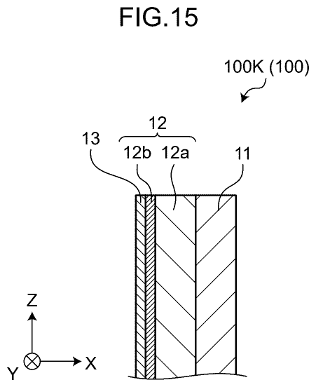

FIG. 14 is a front view of the heater 12 that is included in an optical module 100K (100) of an eleventh embodiment. Further, FIG. 15 is a cross-sectional view taken along a line XV-XV in FIG. 14. As illustrated in FIG. 14 and FIG. 15, in the present embodiment, a resistance temperature detector wiring layer 13 is arranged on a surface of the transparent electric heating element 12b on the opposite side of the etalon filter 11 across the transparent base material 12a. The resistance temperature detector wiring layer 13 includes two end portions 13t and 13t and an extended portion 13a. The extended portion 13a extends while being curved with a predetermined width and thickness (height) on the surface of the transparent electric heating element 12b between the two end portions 13t and 13t. In the present embodiment, the extended portion 13a extends in an inverted U shape that is opened toward an opposite direction of the Z direction on the outside of the passing area A, that is, at a location outside the passing area A. The resistance temperature detector wiring layer 13 is formed of a Ti—Pt laminated metal film, for example. According to the present embodiment, it is possible to achieve the same effects as the first embodiment as described above, and it is possible to estimate the temperature of the etalon filter 11 based on a resistance value of the resistance temperature detector wiring layer 13, so that it is possible to further improve wavelength control accuracy. The resistance temperature detector wiring layer 13 is one example of a temperature detection unit. Meanwhile, specifications, such as the location and the shape, of the resistance temperature detector wiring layer 13 are not limited to the example illustrated in FIG. 14.

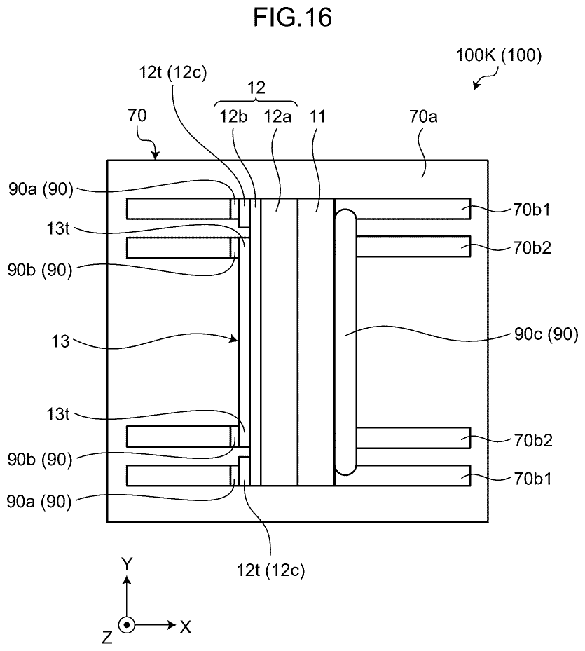

FIG. 16 is a plan view of a part of the optical module 100K. As illustrated in FIG. 16, on the top surface (surface) 70a of the heat shielding member 70, two wiring patterns 70b1 that extend in an approximately parallel manner in the X direction (optical axis direction) with a predetermined width in the Y direction, and two wiring patterns 70b2 that extend in an approximately parallel manner in the X direction with a predetermined width in the Y direction are arranged. Each of the wiring patterns 70b1 as conductors is electrically connected to an end portion 12t of the wire unit 12c via a bonding material 90a (90). Further, each of the wiring patterns 70b2 as conductors is electrically connected to an end portion 13t of the resistance temperature detector wiring layer 13 via a bonding material 90b (90). The bonding materials 90a and 90b are conductive bonding materials that have conductivity, and are, for example, solders, conductive adhesives, or the like. Furthermore, an end portion of the etalon filter 11 in the opposite direction of the Z direction is bonded to the top surface 70a and the wiring patterns 70b1 and 70b2 via a bonding material 90c (90). The bonding material 90c is an insulating bonding material with insulating property, and is, for example, a synthetic resin adhesive. With this configuration, it is possible to firmly fix an end portion of the assembly of the etalon filter 11 and the heater 12 in the opposite direction of the Z direction at end portions on both sides in the X direction on the heat shielding member 70 via the bonding material 90. Moreover, the bonding materials 90a electrically connect the wire units 12c and the wiring patterns 70b1, and the bonding materials 90b electrically connect the resistance temperature detector wiring layer 13 and the wiring patterns 70b2. with this configuration, it is possible to use the bonding materials 90a and 90b for fixation of the sub assembly and electrical connection between the conductors; therefore, as compared to a case in which a bonding material is arranged for each of the fixation of the sub assembly and the electrical connection between the conductors, it is possible to reduce the number of the bonding materials and reduce efforts and costs needed for bonding operation, for example. The bonding materials 90a and 90b are referred to as conductive bonding materials, and the bonding material 90c is referred to as an insulating bonding material.

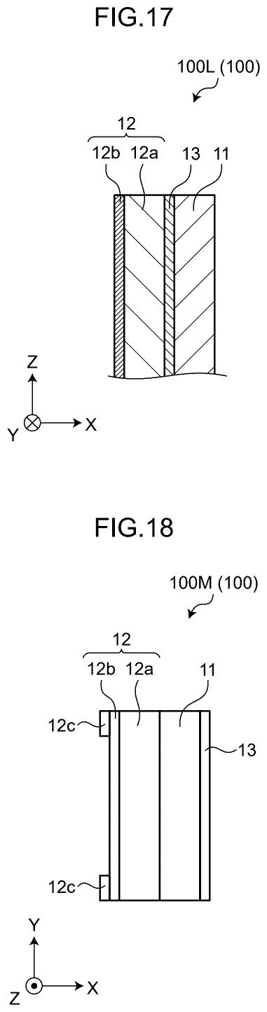

FIG. 17 is a cross-sectional view, at the same position as in FIG. 15, of the etalon filter 11, the heater 12, and the resistance temperature detector wiring layer 13 that are included in an optical module 100L (100) of a twelfth embodiment. Further, FIG. 18 is a plan view of the etalon filter 11, the heater 12, and the resistance temperature detector wiring layer 13 that are included in an optical module 100M (100) of a thirteenth embodiment. In the twelfth embodiment, as illustrated in FIG. 17, the resistance temperature detector wiring layer 13 is arranged between the etalon filter 11 and the transparent base material 12a. Furthermore, in the thirteenth embodiment, as illustrated in FIG. 18, the resistance temperature detector wiring layer 13 is arranged on the opposite side of the heater 12 across the etalon filter 11. Even with this configuration, it is possible to achieve the same effects as the first embodiment.

Thus, the embodiments and the modifications are described above, but the embodiments and the modifications are examples, and do not limit the scope of the disclosure. The embodiments and the modifications may be embodied in various different modes, and various omission, replacement, combinations, and modifications may be made within the scope not departing from the gist of the disclosure. Furthermore, each of the configurations and specifications, such as shapes (structures, types, directions, models, sizes, lengths, widths, thicknesses, heights, numbers, arrangement, locations, materials, and the like), may be appropriately changed in embodiments.

For example, the transparent electric heating element may be arranged in the etalon filter, instead of being arranged in the transparent base material.

According to the present disclosure, for example, it is possible to achieve an optical apparatus and a wavelength-tunable laser that are improved and novel and that are able to individually adjust temperature of an optical filter with improved accuracy.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical apparatus comprising:
a base;
a plurality of optical components fixed to the base, the plurality of optical components including an etalon filter; and
an electric heating member integrated with the etalon filter, the electric heating member including a transparent electric heating element configured to be optically in series with the etalon filter and transmit light.

2. The optical apparatus according to claim 1, wherein the electric heating member includes a transparent base material configured to be optically in series with the etalon filter and the transparent electric heating element and transmit the light, the transparent base being arranged on a surface of the transparent electric heating element.

3. The optical apparatus according to claim 2, wherein the transparent electric heating element is arranged on an opposite side of the etalon filter across the transparent base material.

4. The optical apparatus according to claim 2, wherein the transparent electric heating element is located between the transparent base material and the etalon filter.

5. The optical apparatus according to claim 1, further comprising:
a wire unit configured to supply electricity to the transparent electric heating element, wherein
the wire unit is arranged on an outside of a light passing area in the transparent electric heating element.

6. The optical apparatus according to claim 1, wherein
the etalon filter includes
a body; and
dielectric films arranged on an input end and an output end of the body, and
the body is made of glass or silicon.

7. The optical apparatus according to claim 1, wherein the transparent electric heating element is made of Indium Tin Oxide.

8. The optical apparatus according to claim 1, wherein the transparent electric heating element is configured to change a temperature of a light passing area of the etalon filter in a range equal to or higher than normal temperature and equal to or lower than 150 degrees Celsius by changing electricity to be supplied.

9. The optical apparatus according to claim 1, further comprising:
a temperature detection unit configured to detect a temperature of one of the etalon filter or the electric heating member.

10. The optical apparatus according to claim 9, wherein the temperature detection unit is a resistance temperature detector wiring layer for which a resistance value changes with a change in temperature.

11. The optical apparatus according to claim 10, wherein
the electric heating member includes a transparent base material configured to be optically in series with the etalon filter and the transparent electric heating element and transmit the light, the transparent base material being arranged on a surface of the transparent electric heating element, and
the resistance temperature detector wiring layer is located on an opposite side of the etalon filter across the transparent base material.

12. The optical apparatus according to claim 10, wherein
the electric heating member includes a transparent base material configured to be optically in series with the etalon filter and the transparent electric heating element and transmit the light, the transparent base material being arranged on a surface of the transparent electric heating element, and
the resistance temperature detector wiring layer is located between the transparent base material and the etalon filter.

13. The optical apparatus according to claim 10, wherein the resistance temperature detector wiring layer is formed of a Ti-PT laminated metal film.

14. The optical apparatus according to claim 1, wherein the electric heating member is arranged between the etalon filter and another heating element that is different from the electric heating member.

15. The optical apparatus according to claim 1, wherein the heat shielding member is arranged between the etalon filter and another heating element that is different from the electric heating member.

16. The optical apparatus according to claim 1, wherein the etalon filter is fixed to one of the base or a different member fixed to the base, via a first bonding material.

17. The optical apparatus according to claim 16, wherein the etalon filter and the electric heating member are bonded together via a second bonding material that has higher thermal conductivity than the first bonding material.

18. A wavelength-tunable laser comprising:
an optical amplification unit configured to generate light, amplify the light, and output the light from a first end portion and a second end portion that is on an opposite side of the first end portion;
a first mirror configured to reflect the light output from the first end portion;
a second mirror configured to reflect the light output from the second end portion;
an etalon filter arranged between the optical amplification unit and the first mirror or the second mirror, the etalon filter having predetermined wavelength characteristics and being configured to transmit the light output from the optical amplification unit; and
an electric heating member integrated with the etalon filter, the electric heating member including a transparent electric heating element configured to be optically in series with the etalon filter and transmit the light.

19. The wavelength-tunable laser according to claim 18, further comprising:
a lens arranged between the optical amplification unit and the etalon filter and configured to transmit light that travels between the optical amplification unit and the etalon filter.

20. The wavelength-tunable laser according to claim 18, further comprising:
a temperature control mechanism configured to adjust a temperature of the optical amplification unit; and
a heat shielding member arranged between the temperature control mechanism and the etalon filter, and configured to prevent thermal conduction between the temperature control mechanism and the etalon filter.
